(19) United States
(12) Patent Application Publication
(10) Pub. No.: US 2025/0298951 A1
(43) Pub. Date: Sep. 25, 2025

(54) DETERMINATIONS OF CORRESPONDING HIERARCHICAL CELLS BETWEEN CIRCUIT DESIGNS

(71) Applicant: Siemens Industry Software Inc., Plano, TX (US)

(72) Inventor: Brian Nelson, Newberg, OR (US)

(73) Assignee: Siemens Industry Software Inc., Plano, TX (US)

(21) Appl. No.: 18/613,355

(22) Filed: Mar. 22, 2024

(51) Int. Cl. G06F 30/3323

(52) U.S. Cl. CPC G06F 30/3323

(57) ABSTRACT

Systems and methods are presented for improved determination of cell correspondences between circuit designs. A method may include steps of accessing a source circuit design and a layout circuit design, accessing previously-determined corresponding hierarchical cells between the source circuit design and the layout circuit design, and determining additional corresponding hierarchical cells between the source circuit design and the layout circuit design, including by constructing a class-correspondence graph for the source circuit design and the layout circuit design, determining components from the class-correspondence graph, constructing a component-containment graph for the components of the class-correspondence, topologically sorting the component-containment graph, processing the components in a top-down topological order to determine the additional corresponding hierarchical cells between the source circuit design and the layout circuit design.

### BACKGROUND

Electronic circuits, such as integrated circuits, are used in nearly every facet of modern society, from automobiles to microwaves to personal computers. Design of circuits may involve many steps, known as a “design flow.” The particular steps of a design flow are often dependent upon the type of circuit being designed, its complexity, the design team, and the circuit fabricator or foundry that will manufacture the circuit. Electronic design automation (EDA) applications support the design and verification of circuits prior to fabrication. EDA applications may implement various EDA procedures, e.g., functions, tools, or features to analyze, test, or verify a circuit design at various stages of the design flow.

### BRIEF DESCRIPTION OF THE DRAWINGS

Certain examples are described in the following detailed description and in reference to the drawings.

FIG. 1 shows an example of a computing system that supports improved determinations of corresponding hierarchical cells between circuit designs according to the present disclosure.

FIG. 2 shows an example construction of a class-correspondence graph from a source circuit design and layout circuit design by the hcell determination engine.

FIG. 3 shows an example determination of components with a class-correspondence graph.

FIG. 4 shows an example construction of a component-containment graph for the components of a class-correspondence graph.

FIG. 5 shows an example processing of a component to determine additional corresponding hierarchical cells.

FIG. 6 shows an example of logic that a system may implement to support improved determinations of corresponding hierarchical cells between circuit designs according to the present disclosure.

FIG. 7 shows an example of a computing system that supports improved determinations of corresponding hierarchical cells between circuit designs according to the present disclosure.

### DETAILED DESCRIPTION

Electronic circuits, such as integrated circuits (ICs), are used in nearly every facet of modern society, from automobiles to microwaves to personal computers. The design, verification, and physical manufacture of circuit devices often involve several steps, sometimes referred to as a “design flow.” The particular steps of a design flow are dependent upon various factors, such as the type of integrated circuit being designed, its complexity, the design team, and the integrated circuit fabricator (e.g., foundry) that will manufacture the physical circuit. Typically, software and hardware tools can verify the circuit designs at various stages of the design flow, for example through complex rule checks, software-based simulations, hardware-based emulation, and various other techniques supported by modern EDA technology. These steps of a design flow aid in the discovery of errors in circuit designs, and allow design teams and engineers to correct or otherwise improve the designs prior to, during, or after physical manufacture.

Several steps are common to most design flows of IC design. Initially, the specification for a new circuit can be transformed into or otherwise generated as a logical design. Logical designs are sometimes referred to as a register transfer level (RTL) description of a circuit. With logical designs, a circuit can be described in terms of both the exchange of signals between hardware registers and the logical operations that are performed on those signals. The logical design typically employs a Hardware Design Language (HDL), such as the Very high-speed integrated circuit Hardware Design Language (VHDL). The logic of the circuit is then analyzed to confirm that the design will accurately perform the functions desired for the circuit. This analysis is sometimes referred to as “functional verification.”

After the accuracy of the logical design is confirmed through functional verification, a logical design can be converted into a device design by synthesis software. The device design, which is typically in the form of a schematic or netlist, can describe the specific electronic devices (e.g., transistors, resistors, and capacitors) that form the circuit design, along with the interconnections between these electronic devices. This device design generally corresponds to the level of representation displayed in conventional circuit diagrams. The relationships between the electronic devices are then analyzed to confirm that the circuit described by the device design will correctly perform the desired functions. This analysis is sometimes referred to as “formal verification.” Additionally, preliminary timing estimates for portions of the circuit are often made at this stage, using an assumed characteristic speed for each device, and incorporated into the verification process.

Once the electronic devices components and their interconnections are established, the design can again be transformed in a design flow. In particular, the next transformation may be to a physical design that describes specific geometric elements that form the circuit design. This type of physical version of a circuit design is often referred to as a “layout” design or “physical layout” (and may simply be referred to as a “layout”). The geometric elements, which typically are polygons, define the shapes that will be created in various layers of material to physically manufacture the circuit. Automated place and route tools can be used to define or generate the physical layouts, especially for wires that will be used to interconnect the circuit devices in the physical representation of the circuit design. Each layer of a circuit can have a corresponding layer representation in the layout design, and the geometric shapes described in a layer representation will define the relative locations of the circuit elements that will make up the circuit device (e.g., of transistors, resistors, capacitors, etc.). For example, shapes in the layer representation of a metal layer will define the locations of the metal wires used to connect the circuit devices.

Integrated circuit layout descriptions can be provided in many different formats. The Graphic Data System II (GDSII) format is a popular format for transferring and archiving two-dimensional graphical IC layout data. Among other features, GDSII contains a hierarchy of structures, each structure containing layout elements (e.g., polygons, paths or poly-lines, circles and textboxes). Other layout formats include an open-source format named Open Access, Milkyway by Synopsys, Inc., EDDM by Siemens EDA (formerly Mentor Graphics Corporation), and the Open Artwork System Interchange Standard (OASIS) format proposed by Semiconductor Equipment and Materials International (SEMI). These various industry formats are used to define the geometrical information in IC layout designs that are employed to manufacture integrated circuits. Once the circuit design is finalized, the layout portion of the design can be used by fabrication tools to manufacture the device using a photolithographic process.

Typically, a designer will perform a number of verification processes on the layout design. For example, the layout design may be analyzed to confirm that it accurately represents the circuit devices and their relationships described in the device design. In this process, a layout-versus-schematic (LVS) tool can extract a netlist from the layout design and compare it with the netlist taken from the circuit schematic. LVS can be augmented by formal equivalence checking, which checks whether two circuits perform exactly the same function without demanding isomorphism.

The layout design also may be analyzed to confirm that it complies with various design requirements, such as minimum spacings between geometric elements and minimum linewidths of geometric elements. Such checks may be part of a design rule checking (DRC) process performed on layout design. DRC tools can take, as an input, a physical layout (e.g., in the GDSII or OASIS standard format) as well as a rule deck which specifies the specific rule checks to perform on the layout design. As checks in a DRC process can be specific to a particular circuit fabrication process, rule decks are typically provided by a foundry or circuit manufacturer specifying the particular rules that circuit designs must adhere to for circuit fabrication via the foundry (e.g., at a specified technology node or specific fabrication process parameters). Put another way, foundry-provided rule decks can include a list of rules specific to the semiconductor fabrication process employed by the foundry or otherwise selected for use in circuit manufacture. As such, a set of rules for a particular fabrication process can be referred to as a run-set, rule deck, or just a deck. An example format used for implementation of rule decks is the Standard Verification Rule Format (SVRF) by Siemens EDA (formerly Mentor Graphics Corporation).

There are many different fabrication processes for manufacturing a circuit, but most processes include a series of steps that deposit layers of different materials on a substrate, expose specific portions of each layer to radiation, and then etch the exposed (or non-exposed) portions of the layer away. For example, a simple semiconductor device component could be manufactured by the following steps. First, a positive-type epitaxial layer is grown on a silicon substrate through chemical vapor deposition. Next, a nitride layer is deposited over the epitaxial layer. Then specific areas of the nitride layer are exposed to radiation, and the exposed areas are etched away, leaving behind exposed areas on the epitaxial layer, (i.e., areas no longer covered by the nitride layer). The exposed areas then are subjected to a diffusion or ion implantation process, causing dopants, for example phosphorus, to enter the exposed epitaxial layer and form charged wells. This process of depositing layers of material on the substrate or subsequent material layers, and then exposing specific patterns to radiation, etching, and dopants or other diffusion materials, is repeated a number of times, allowing the different physical layers of the circuit to be manufactured.

Each time that a layer of material is exposed to radiation, a photomask (mask) must be created to expose only the desired areas to the radiation, and to protect the other areas from exposure. The mask is created from circuit layout data. That is, the geometric elements described in a physical layout define the relative locations or areas of the circuit wafer that will be exposed to radiation through the mask. A mask or reticle writing tool is used to create the mask based upon the design layout, after which the mask can be used in a photolithographic process for fabrication of physical circuits. One or more resolution enhancement techniques (RETs) are often employed to improve the resolution of the image that the mask forms on the substrate during the photolithographic process. One of these techniques is optical proximity correction (OPC). OPC can be rule-based, model-based, or both. In rule-based OPC, the proximity effects are characterized, and specific solutions are devised for specific geometric configurations. The layout design is then searched using a DRC tool or a geometric-based software engine to find these geometric configurations. Once they are found, the specific solutions are applied. Through various steps of a design flow, the design, manufacture, and fabrication of circuits can be performed and supported through EDA technology.

While various steps of a design flow are described herein, circuit manufacture processes continue to evolve and may include any additional or alternative flow steps. Moreover, the intricacy of each step in a design flow is immense, especially as circuit designs continue to increase in complexity and the transistors and other devices that form a circuit are merely a few atoms wide. As such, accurate and effective design flow steps may increase the efficiency of circuit design and improvements at any given step in the design flow can yield significant benefits.

One portion of the design flow that can benefit from improved efficiency and effectiveness is the LVS step. In LVS processes, IC design verification can involve comparing two versions of a circuit design to determine whether the compared circuits are equivalent. Often times, LVS involves the comparison of a physical layout with a circuit schematic, digital or logical circuit design, or another design form in order to verify that the generated physical layout properly effectuates intended design behavior. Circuit designs are often represented as a hierarchical structure. In such hierarchical structures, circuit designs can be represented through hierarchical cells (or simply referred to as cells). A hierarchical cell may refer to any circuit design object that can be defined as well as used (e.g., referenced) in the definition of an overall circuit design or in the definition of other cells in the circuit design. As such, the design of a given hierarchical cell may reference or contain instances of other cells, which may in turn reference or contain instances of other different cells, leading to a hierarchy of cells in an overall circuit design. Cells within a circuit design can be referenced any number of times, and each use or reference to a given cell in the circuit design can be referred to as an instance of the given cell.

For circuit design equivalence comparisons, one possibility is to compare the “flattened” version or each circuit in which every cell instance in each of the compared circuit designs is replaced with the defined contents of the cell. Such a process may be referred to as a “flattening” because hierarchies and cells are replaced with the designed content and the entire circuit design is represented without any cells or hierarchies. However, with the continuously increasing complexities in modern circuit designs that can include billions of circuit elements, often times more, the computational latency and resource requirements for such flattening operations for direct circuit comparisons have become time-prohibitive and cost-prohibitive.

As another possibility for circuit design equivalence comparisons, hierarchy-based circuit comparisons have been developed to improved speed and efficiency. In such hierarchy-based circuit comparisons, two different circuit designs are compared on a cell-by-cell basis as specified according to the different hierarchies and cell instances present in the two compared designs. However, with such comparisons, including within an LVS context, the cell hierarchies of the two compared circuit designs typically do not match. This is the case when a one-to-one correspondence does not exist between each hierarchical cell in one compared circuit design to each hierarchical cell in the other compared circuit design. There may be some cell correspondences that exist, but at least some of the cells in one of the compared circuits do not correspond to any cells in the other compared circuit and vice versa. Thus, for any cells in a circuit design without a correspondence to a cell in the other compared circuit design, flattening must be performed in order to properly compare the two circuit designs. Corresponding cells between the circuit designs need not be flattened, and can be directly equated as equivalent based on specified correspondences. Thus, the greater the degree at which hierarchical cell correspondences are specified between two compared circuits, the less flattening operations need be performed and the greater the efficiency of circuit comparison processes.

As used herein, a correspondence or correspondence relationship between cells of circuit designs may refer to any form of specifying an equivalence relationship between the cells. Such a correspondence may also be referred herein to as corresponding hierarchical cells. Correspondence mechanisms may include any format to express an equivalence between cells of two different circuit designs. In some EDA contexts, corresponding hierarchical cells are referred to as “hcells” and the terms hcell, hcell correspondence, hcell relationship, and the like, are also used herein to refer to corresponding hierarchical cells. Modern EDA systems often provide capabilities to express correspondences or otherwise link cells in two different circuit designs. For example, in LVS processes, an EDA tool can prompt or require a user to directly specify which cells in one circuit design correspond to which cells in another circuit design. Manual specification of corresponding hierarchical cells for LVS comparisons is one technique by which EDA systems can support reduction of flattening operations in LVS circuit comparisons. Note that corresponding hierarchical cells necessarily require cells from two different circuit designs, but need not be on a one-to-one basis. It is possible for multiple cells (e.g., cells with different names) from one circuit design to correspond with a single cell of another circuit design. Such correspondences can be referred as many-to-one corresponding hierarchical cells or many-to-one hcells.

A longstanding challenge in LVS processes is the specification of useful corresponding hierarchical cells. While LVS processes can proceed without specification of correspondences for every cell of compared circuit designs, the greater the degree of hierarchy coverage of specified corresponding hierarchical cells, the greater to potential improvement in run-time latencies and memory consumption. Manual hcell specification that completely specify the entirety of correspondence relationships between all equivalent cells between circuit designs is near impossible for modern circuit designs that can encompass billions of circuit elements designed across tens of different design teams, hundreds of engineers, and across different design cycles. Some automated determinations of corresponding hierarchical cells have been developed, but face various challenges. Any corresponding hierarchical cells (whether user-specified or EDA system-determined) should link different circuit design cells that are, in fact, equivalent to one another. Otherwise, the LVS comparison may produce improper results—e.g., reporting that two compared circuits are not equivalent when they actually are or reporting that two compared circuits are equivalent when they actually are not. Report of a false correct result (in which two non-equivalent circuits are reported as equivalent) is a particularly problematic output for LVS processes, which can significantly impact circuit design verifications.

As noted herein, conventional techniques exist to identify corresponding hierarchical cells for circuit design comparisons. Some corresponding hierarchical cells may be specified up front by circuit designers or vendors of circuit design cells. Cells with identical names in two compared circuits may be strong candidates for correspondence. Smaller-sized cells with easily comparable or obvious equivalence might be user-selected (e.g., basic logic gates). Also, naming conventions used by tools that generated the two compared circuits can be leveraged to identify candidates of corresponding hierarchical cells that can be subject to further manual inspection.

Various automatic techniques for determination of corresponding hierarchical cells can be employed. Cells may be automatically matched by matching cell names, or by matching cell names against specified text patterns. Different instance counts or other heuristic metrics in a top-level circuit or other intermediate circuit blocks may be used to eliminate candidates. Performance metrics may be used to reduce a large set of potential hcells to a smaller set with a sufficient performance improvement potential, which helps eliminate candidates probabilistically. Some EDA systems can employ bad-hcell prediction capabilities, which can attempt to predict hcells based on cell contents that may lead to false-incorrect comparison results. Some EDA systems may employ expand-on-error processing techniques, which may involve using errors generated by an LVS comparison run between two circuit designs to attempt identification and removal of bad hcells (e.g., incorrectly-specified equivalence relationships between cells of the two circuit designs), and then automatically restart the comparison process. While some corresponding hierarchical cells determination techniques are available, continued improvement in efficiency and accuracy of corresponding hierarchical cells determinations for circuit design comparisons can improve LVS run-times and improve computational efficiency of EDA systems.

The disclosure herein may provide systems, methods, devices, and logic for improved determinations of corresponding hierarchical cells between circuit designs. The various technical features presented herein may be collectively referred to as corresponding hierarchical cells determination technology, and the disclosure may provide intelligent algorithmic determinations of additional corresponding hierarchical cells using heuristics based on detected identical-cell classes, previously-determined corresponding hierarchical cells, cell-instance containment metrics, or combinations thereof. As example technical features, the corresponding hierarchical cells determination technology may support or leverage multiple distinct types of equivalence relations, identicality and correspondence (along with a transitive property of equivalence) in order to identify classes of equivalent cells within circuit designs. Such equivalent cell classes can be considered candidates for additional corresponding hierarchical cells determinations. The corresponding hierarchical cells determination technology may approach such equivalent cell class detections through construction of class-correspondence graphs and identifying connected components, as described in greater detail herein. As also described herein, the corresponding hierarchical cells determination technology may support evaluation of additional corresponding hierarchical cells candidates through circuit-based heuristics, such as hierarchy data, in order to identify stronger performance-improvement candidates with increased confidence of accuracy. Ranking of candidates is also described herein, including selection of higher confidence candidate options that include the same cell.

Through the various technical features described herein, the corresponding hierarchical cells determination technology of the present disclosure may improve upon conventional correspondence determinations through algorithmic determination of additional hcell relationships that can make higher quality choices due do the inclusion of identicality factors in the considered cell candidates as well as the sophistication of the heuristic methods employed to select among candidate combinations. Through the various corresponding hierarchical cells determination features described herein, improvement to EDA computing systems can be achieved. Identification of additional accurate cell correspondences between circuit designs can (at times, significantly) improve the run-time and reduce the computational requirements of LVS processes or any EDA step that involves circuit comparisons. The automated and data-based algorithmic techniques presented herein can provide intelligent and efficient mechanisms for hcell determinations and remove the error-prone and unreliable nature of manual correspondence specifications and text-based hcell specification processes. As such, the corresponding hierarchical cells determination technology of the present disclosure may provide various technical improvements to EDA computing systems.

These and other aspects of the corresponding hierarchical cells determination technology according to the present disclosure and the technical benefits of such are described in greater detail herein.

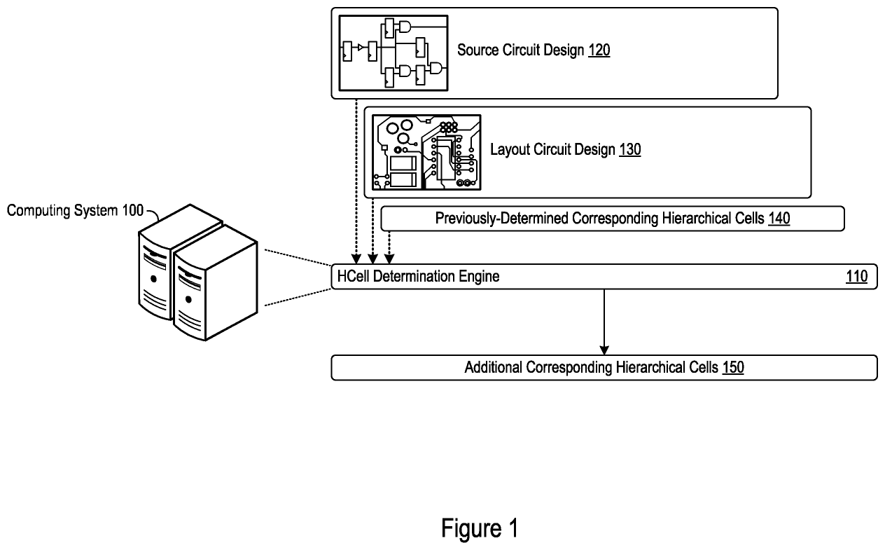

FIG. 1 shows an example of a computing system that supports improved determinations of corresponding hierarchical cells between circuit designs according to the present disclosure. The computing system 100 may take the form of a single or multiple computing devices such as application servers, compute nodes, desktop or laptop computers, smart phones or other mobile devices, tablet devices, embedded controllers, and more. In some implementations, the computing system 100 hosts, instantiates, executes, supports, or implements an EDA application or EDA system that supports circuit design and analysis, and may accordingly provide or implement any of the corresponding hierarchical cells determination technology described herein.

As an example implementation to support any combination of the corresponding hierarchical cells determination technology described herein, the computing system 100 shown in FIG. 1 includes an hcell determination engine 110. The computing system 100 may implement the hcell determination engine 110 (including components thereof) in various ways, for example as hardware and programming. The programming for the hcell determination engine 110 may take the form of processor-executable instructions stored on a non-transitory machine-readable storage medium and the hardware for the hcell determination engine 110 may include a processor to execute those instructions. A processor may take the form of single processor or multi-processor systems, and in some examples, the computing system 100 implements multiple engines using the same computing system features or hardware components (e.g., a common processor or a common storage medium).

In operation, the hcell determination engine 110 may access a source circuit design and a layout circuit design, such as the source circuit design 120 and the layout circuit design 130 shown in FIG. 1. As used herein, a source circuit design and layout circuit design may refer to any two different circuit designs that can be compared. As such, the source circuit design 120 and the layout circuit design 130 may be of any format, representation, or produced as part of any step of an EDA design flow. In the LVS context, the source circuit design 120 may take the form of a device schematic or any data representation generated thereof (e.g., an extracted netlist, a graph representation of the cell hierarchy, etc.) and the layout circuit design 130 may take the form of a physical layout or any data representation generated thereof (e.g., an extracted netlist, a graph representation of the cell hierarchy, etc.). The hcell determination engine 110 may access the source circuit design 120 and the layout circuit design 130 in any suitable manner, e.g., loading the circuit designs from memory, receiving the circuit designs across a communication network, through user-selection or input designs, etc.

In operation, the hcell determination engine 110 may also access previously-determined corresponding hierarchical cells 140 between the source circuit design 120 and the layout circuit design 130. The previously-determined corresponding hierarchical cells 140 can include any user or manually-specified hcell relationships or correspondences, any automatically determined correspondences using conventional techniques (e.g., text comparisons), or any combinations thereof. Then, the hcell determination engine 110 may determine additional corresponding hierarchical cells 150 between the source circuit design 120 and the layout circuit design 130, which may include any additionally determined equivalence correspondences between the source circuit design 120 and the layout circuit design 130.

The hcell determination engine 110 may determine the additional corresponding hierarchical cells 150 through various algorithmic steps, including by constructing a class-correspondence graph for the source circuit design 120 and the layout circuit design 130. Within the class-correspondence graph, a given node in the may represent a set of identical cells in the source circuit design 120 or a set of identical cells in the layout circuit design 130. Edges between nodes in the class-correspondence graph can be specified based on the previously-determined corresponding hierarchical cells 140. Features of the construction and use of the class-correspondence graph are described in greater detail herein. In determining the additional corresponding hierarchical cells 150, the hcell determination engine 110 may determine components from the class-correspondence graph, and each component in the class-correspondence graph may be a disjointed sub-graph in the class-correspondence graph.

The hcell determination engine 110 may then construct a component-containment graph for the components of the class-correspondence graph. Each node in the component-containment graph may represent a component from the class-correspondence graph and directed edges in the component-containment graph may specify that a given cell in a given component contains an instance of another cell from another component. The hcell determination engine 110 may also topologically sort the component-containment graph and process the components in a top-down topological order to determine the additional corresponding hierarchical cells 150 between the source circuit design 120 and the layout circuit design 130. The processing of the components by the hcell determination engine 110 may intelligently leverage various heuristics, such as hierarchical data, instance containment-metrics, and more, in order to identify and select correspondence candidates from the equivalent cell classes as the determined additional corresponding hierarchical cells 150. In operation, the hcell determination engine 110 may also perform a circuit comparison between the source circuit design 120 and the layout circuit design 130 using the determined additional corresponding hierarchical cells 150.

These and other aspects of the corresponding hierarchical cells determination technology of the present disclosure are described in greater detail next.

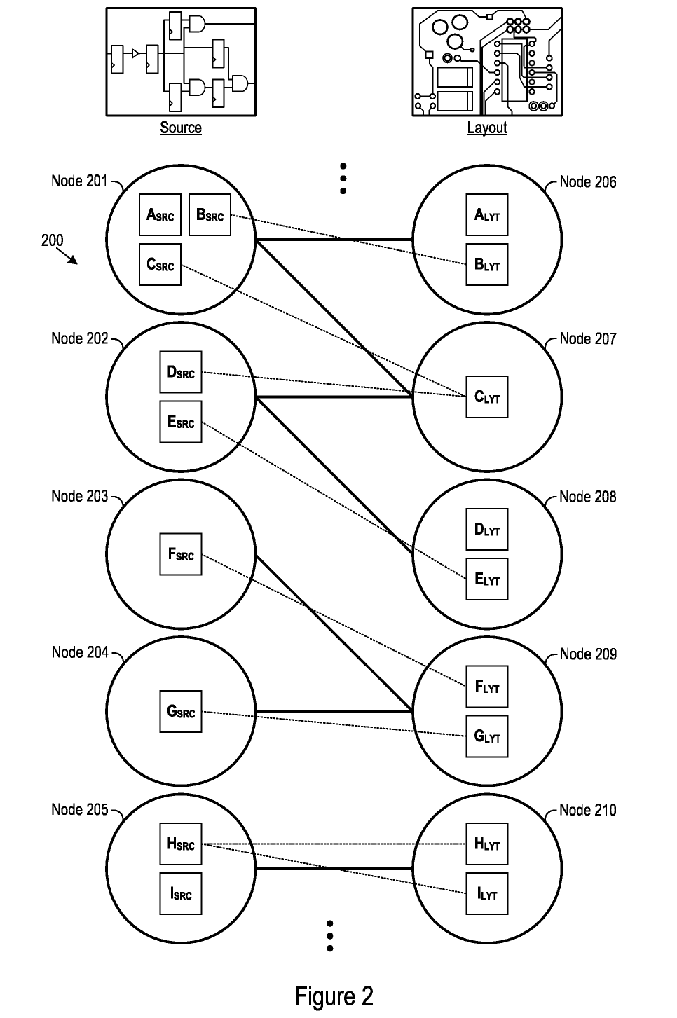

FIG. 2 shows an example construction of a class-correspondence graph from a source circuit design 120 and layout circuit design 130 by the hcell determination engine 110. In the example shown in FIG. 2, the hcell determination engine 110 constructs a class-correspondence graph of which a portion is shown as the graph portion 200. The hcell determination engine 110 may generate the class-correspondence graph as a graph data structure whose nodes are identical-cell classes and whose edges are induced by previously-determined correspondences. Each node in the class-correspondence graph may thus represent a class of identical cells from the source circuit design 120 or the layout circuit design 130. As an illustrative example of edge insertion, if any cell in an identical-cell class of the source circuit design 120 corresponds to a cell in the layout circuit design 130 in another identical-cell class D, then the hcell determination engine 110 inserts an edge between nodes for the classes C and D in the class-correspondence graph. The hcell determination engine 110 may construct the class-correspondence graph such that each identical-cell class (e.g., as represented by each node) contains either identical source cells or identical layout cells, but not both. The class-correspondence graph may thus be a bipartite graph in which each edge exists between a node for the source circuit design 120 and a node for the layout circuit design 130.

To construct a class-correspondence graph, the hcell determination engine 110 may identify any cells in the source circuit design 120 that are identical to one another and group such a class of cells into a single node in the class-correspondence graph. The hcell determination engine 110 may perform the same operation for the layout circuit design 130 as well. Thus, a give node in the class-correspondence graph may represent a class of identical cells from the source circuit design 120 or from the layout circuit design 130, but not cells from both. To determine the identical-cell classes of a circuit design, the hcell determination engine 110 may analyze the cells that form the circuit design according to any number of cell identicality criteria. In some implementations, the hcell determination engines 110 may detect identical cells from a circuit design such that the detected cells differ only in name, but are otherwise identical. Thus, detected identical cells may have identical device properties, identical connections and instance counts within the circuit design, identical traced properties (e.g., device properties identified in a rule deck as significant to a circuit comparison process), etc. Other cell identicality criteria applied by the hcell determination engine 110 may be more lax in requirements, and can be user-configured or system specified.

Detection of identical cells within a circuit design (e.g., the source circuit design 120) may be computationally intense, especially as the number of cells in the circuit design may be immense. This may be especially the case for full-chip designs in which multiple design teams separately or independently develop specific portions of the circuit design. Different design teams may rename standard cells or other basic design blocks to ensure the specifically-used version of the cell is not inadvertently altered by other design teams or other steps in an EDA design flow. Thus, a full circuit design may include numerous cells, and the hcell determination engine 110 may treat cells with different names or IDs as distinct cells for identical-cell determination processes. The hcell determination engine 110 may detect identical cells within a circuit design through various processing techniques. For example, the hcell determination engine 110 may first group the cells of a circuit design according to various cell properties, such as number of nets, number of cell instances, etc. Such a sort based on cell-properties may be quickly performed, and any cell without any other cell in its cell-property grouping may be filtered from the identical cell detection process. Note that any filtered cell (e.g., with unique cell properties, such as instance count) may, by itself, form an identical-cell class (and thus be represented as a node with a single cell in the class-correspondence graph). An identical-cell class with a single cell may be referred to as a trivial class.

After such filtering, the hcell determination engine 110 may apply a secondary processing of the grouped cells. Such a secondary processing may be in the form of hash computation performed for each cell of a group (e.g., cell characteristics thereof aside from cell name), such as topological hash computation. For any cells in a group with mismatching or unique topological hash values, these cells may be filtered from consideration, and form a separate single cell class. For each cell grouping with more than one cell remaining after the hash-based filtering, the hcell determination engine 110 may then further analyze, examine, or compare the cells to determine whether the cell identicality criteria are satisfied. Any individual cell that fails the identicality criteria may be separated into a single-cell class and multiple cells that satisfy the identicality criteria may be grouped into the same identical-cell class. In such a manner, the hcell determination engine 110 may identify identical cell classes with multiple cells within a circuit design. The hcell determination engine 110 may represent each identified class as a separate node in a constructed class-correspondence graph. Note that for

An example portion of a class-correspondence graph is shown in FIG. 2. The graph portion 200 in FIG. 2 includes nodes 201-205 for identical cell classes of the source circuit design 120 and nodes 206-210 for identical cell classes of the layout circuit design 130. As seen in FIG. 2, node 201 may represent a class of identical cells in the source circuit design 120 that includes the cells labeled as A_{SRC}, B_{SRC}, and C_{SRC}. Node 202 may represent a class of identical cells in the source circuit design 120 that includes the cells labeled as D_{SRC} and E_{SRC}, node 203 may represent a class of identical cells in the source circuit design 120 that includes a single cell labeled as F_{SRC} (and node 203 may thus represent a trivial class), and so forth for nodes 204 and 205. As also in FIG. 2, node 206 may represent a class of identical cells in the layout circuit design 130 that includes the cells labeled as A_{LYT} and B_{LYT}. Node 207 may represent a class of identical cells in the layout circuit design 130 that includes the single cell labeled as C_{LYT}, node 208 may represent a class of identical cells in the layout circuit design 130 that includes the cells labeled as D_{LYT} and E_{LYT}, and so forth for nodes 209 and 210.

The hcell determination engine 110 may insert edges into the class-correspondence graph based on accessed input hcells, e.g., the previously-determined corresponding hierarchical cells 140. Each correspondence in the previously-determined corresponding hierarchical cells 140 may link one or more cells from the source circuit design 120 to one or more cells in the layout circuit design 130, and each link between cells of the source circuit design 120 and layout circuit design 130 can be represented through an edge in the class-correspondence graph. In the example of FIG. 2, correspondences of the previously-determined corresponding hierarchical cells 140 are depicted through dotted lines between individual cells in the graph portion 200. For any identical-cell class of the source circuit design 120 that includes a cell that corresponds to a cell of an identical-cell class of the layout circuit design 130, then the hcell determination engine 110 inserts an edge between the nodes that represent the identical-cell classes. Thus, the class-correspondence graph shown in FIG. 2 includes an edge between node 201 and node 206 as the previously-determined corresponding hierarchical cells 140 may specify a correspondence between cell A_{SRC} of the source circuit design 120 and cell B_{LYT} of the layout circuit design 130. Other edges between nodes of the class correspondence graph are illustrated in FIG. 2 for the cell correspondences visually depicted through the dotted lines linking different cells. Note that even though there are two dotted lines connecting nodes 205 and 210, the hcell determination 110 may insert only a single edge between these two identical-cell classes in the class-correspondence graph.

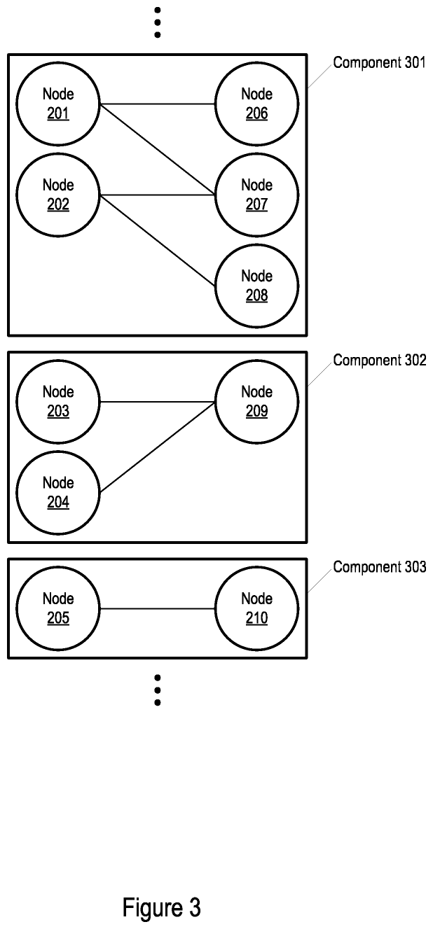

In any such manner as described herein, the hcell determination engine 110 may construct a class-correspondence graph for two circuit designs. The hcell determination engine 110 may process the class-correspondence graph to determine components within the class-correspondence graph, various features of which are described next with reference to FIG. 3.

FIG. 3 shows an example determination of components with a class-correspondence graph. A component may refer to a partition of a class-correspondence graph that is comprised of a set of nodes (representing a set of identical-cell classes) and the edges between them. The hcell determination engine 110 may determine the sets of nodes and edges that form components such that any two nodes with an edge between them are in the same given component, and any node in a given component is reachable on some path through nodes and edges from any other node in the given component. Thus, the hcell determination engine 110 may determine each component of a class-correspondence graph as a disjoint subgraph of the overall class-correspondence graph. The hcell determination engine 110 may apply or implement any suitable technique, algorithm, or graph processing capability to partition the class-correspondence graph into distinct components. An example algorithm that the hcell determination engine 110 may apply is the depth-first search (DFS) algorithm to determine components from the class-correspondence graph.

In FIG. 3, the hcell determination engine 110 determines the components 301, 302, and 303 from the class-correspondence graph. Note that each cell may be present within exactly one identical-cell class (e.g., within a single node), and that every identical-cell class may exist in exactly one component of a class-correspondence graph. The hcell determination engine 110 may further characterize components in different ways. For example, the hcell determination engine 110 may classify a given component as a trivial component responsive to a determination that the given component contains no nontrivial classes (that is, contains no identical-cell classes having more than one cell) or that the given component contains only a single class in which no cell corresponds to a cell in the other circuit design. Use of trivial components is described later.

Note that components determined by hcell determination engine 110 may exhibit various characteristics. The cells of the same component are, in some sense, equivalent to each other. When two cells are identical, there exists and equivalency relationship. When two cells from different circuit designs correspond through hcell relationships, they are specified as equivalent to one another. As equivalence can be understood as a transitive relation, then since each cell in a given component is related to every other cell in the component through some set of identicality and/or correspondence relationships, then each of the cells that form a component can be considered as equivalent. If any of the specified correspondences (e.g., edges) in the component is incorrect, or if corresponding cells are not in fact equivalent due to LVS discrepancies, then the equivalence assumption within a component may be incorrect. However, upon reliance that the correspondence data provided by a user or previously-determined automatically are correct, then the cells in a given component can be considered equivalent, and the hcell determination may rely upon such input data for determination of additional corresponding hierarchical cells based on the provided input data.

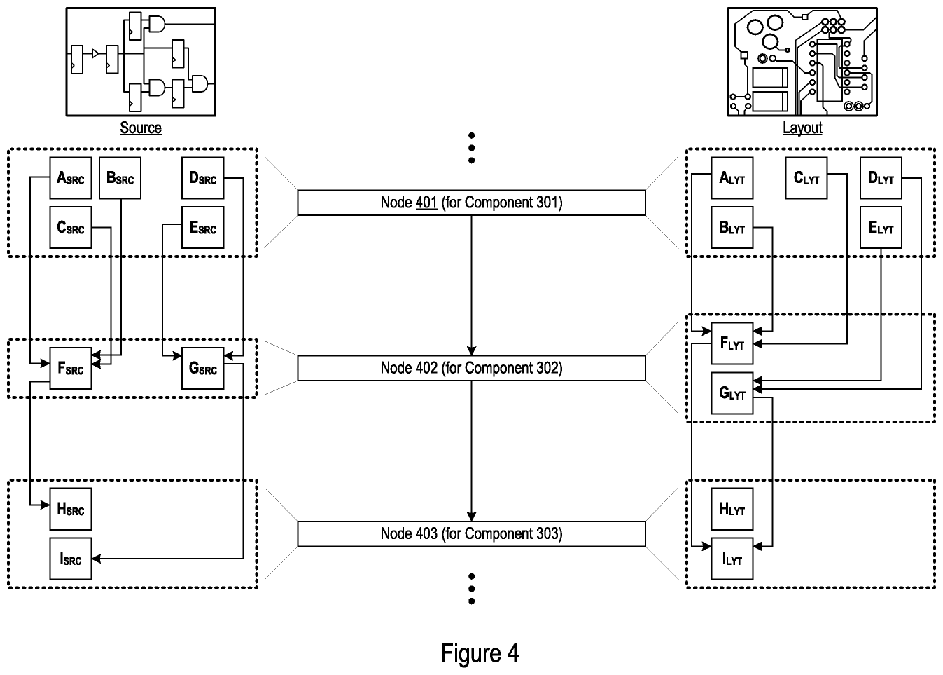

Based on the equivalence assumption for cells within the same component, the hcell determination engine 110 may determine any additional corresponding hierarchical cells as between a non-corresponding cell in a given component to another cell in the same given component, as described in further detail below. Continuing the description of the corresponding hierarchical cells determination technology of the present disclosure, the hcell determination engine 110 may construct a component-containment graph for the components of a class-correspondence graph. Example features of such are described next with reference to FIG. 4.

FIG. 4 shows an example construction of a component-containment graph for the components of a class-correspondence graph. The hcell determination engine 110 may construct a component-containment graph as a directed graph whose nodes are the components of the class-correspondence graph and whose edges are specified according to cell instance containment. To illustrate, the hcell determination engine 110 may construct a component-containment graph such that if any cell in a given component X contains an instance of another cell in a different component Y, then a directed edge is included in the component-containment graph from component X to component Y.

An example of a component-containment graph is shown in FIG. 4, which includes a node 401 for component 301 determined from the class-correspondence graph of FIG. 2, a node 402 for the component 302, and a node 403 for the component 303. Directed edges are included in the component-containment graph from node 401 to node 402 as well as from node 402 to 403. The directed edges may indicate that one or more cells in component 301 include instances of one or more cells in component 302 and that one or more cells in component 302 include instances of one or more cells in component 303. These cell-containment relationships are illustrated in FIG. 4 as well, including for the source circuit design 120 (shown to the left of the nodes 401-403 in FIG. 4) and the layout circuit design 130 (shown to the right of the nodes 401-403 in FIG. 4). In some implementations, the component-containment graph includes (e.g., as underlying data) the cell-containment relationships of individual cells in the source circuit design 120 and the layout circuit design 130.

For the illustrated cell-containment relationships of the source circuit design 120, cells A_{SRC}, B_{SRC}, C_{SRC}, D_{SRC}, and E_{SRC} of component 301 are shown with directed arrows to cells F_{SRC} and G_{SRC} of component 302. In FIG. 4, a directed arrow between two cells indicates a cell-containment relationship, and it can be seen in FIG. 4 that cell A_{SRC} of component 301 includes at least one instance of cell F_{SRC} of component 302. Thus, a directed edge is inserted from node 401 (for component 301) to node 402 (for component 302) in the component-containment graph. Various other cell-containment relationships are depicted for the cells of the source circuit design 120 in components 301, 302, and 303 respectively. Similarly in FIG. 4, cell-containment relationships are illustrated for cells of the layout circuit design 130 as well. As an illustrative example, it can be seen in FIG. 4 that cell B_{LYT} of component 301 includes at least one instance of cell F_{LYT} of component 302. Thus, a directed edge is inserted from node 401 (for component 301) to node 402 (for component 302) in the component-containment graph. Various other cell-containment relationships are depicted for the cells of the layout circuit design 130 in components 301, 302, and 303 respectively. Though several cell-containment relationships may exist between cells of two components, the hcell determination engine 110 may insert only a single directed edge between component nodes of the component-containment graph to indicate such cell-containment relationships.

Note that for a component-containment graph, each component may be reachable via some path from a top-level component. A top-level component may refer to a component that includes cells at a highest level of hierarchy among the two circuit designs. In some examples, the top-level component can necessarily include the two top-level cells in trivial identical-cell classes. Since each cell in a circuit design is directly or indirectly contained by a top level and since identical cells must contain instances of the same underlying cells, an abnormality exists for a top-level cell to be identical to another cell in the same circuit design. This abnormality can take the form of a cycle in the cell-containment relationships for a given circuit design (e.g., the cell containment relationships for the source circuit design 120 or for the layout circuit design 130). Such a cycle at top-level cells is an error condition that is typically detected by EDA systems when circuit graph representations are constructed in memory (e.g., prior to the additional corresponding hierarchical cells determination processes performed by the hcell determination engine 110). As such, the hcell determination engine 110 may construct component-containment graphs such that top-level cells are trivial identical-cell classes in which a top-level cell of the source circuit design 120 corresponds only to a top-level cell of the layout circuit design 130 and vice versa. In such an example topology, note that every cell in a given circuit design is directly or indirectly contained by the top-level cell. It follows then that the top-level component (e.g., node thereof) in the component-containment graph can reach any component (e.g., node thereof) in the component-containment graph through a path of intermediate nodes or directed edges.

Note, also, that identical cells (e.g., of the same identical-cell class) will include instances of the same contained cells. As an illustrative example, if cell A is identical to cell B and cell A contains an instance of cell C, then it follows that cell B also contains an instance of cell C. As such, outgoing cell-containment relationships for a given circuit design will be the same for all cells part of the same identical-cell class. This is also illustrated in FIG. 4, for example through identical cells A_{SRC}, B_{SRC}, and C_{SRC} of the source circuit design 120, each of which have the same cell-contain relationship that include one or more instances of cell F_{SRC} of the source circuit design 120.

As part of corresponding hierarchical cells determination processes, the hcell determination engine 110 may topologically sort the component-containment graph, which can allow the hcell determination engine 110 to process the components in a top-down order. A topological sort may refer to any process by which the hcell determination engine 110 arranges the components of the component-containment graph in a topological ordering based on the directed edges in the component-containment graph. A topological ordering may refer to an ordering in which a given component appears earlier (e.g., closer to the top of the order) than any other component that the given component has a directed edge into. Thus, a top-level component with a directed edge into other components, but without any directed edges into the top-level component, would be topologically sorted by the hcell determination engine 110 to the top of the ordering.

Note that with directed edges, the component-containment graph constructed by the hcell determination engine 110 may be a directed graph. If the component-containment graph does not include any cycles, then the component-containment graph may take the form of a directed acyclic graph. As each directed acyclic graph has at least one valid topological ordering (and in some cases multiple), the hcell determination engine 110 may topologically sort the component-containment graph when it does not include any cycles. The hcell determination engine 110 may topologically sort the component-containment graph using any suitable sorting algorithm, such as depth-first-search or any other sorting process or technique. The sorting technique applied or implemented by the hcell determination engine 110 may output a bottom-up topological ordering, and the hcell determination engine 110 can obtain a top-down ordering by simply reversing the order of the component nodes.

In some instances, the hcell determination engine 110 may detect one or more cycles in a component-containment graph. In such instances, a topological sort performed may fail. In response to detecting a cycle in the component containment graph, the hcell determination engine 110 may terminate the corresponding hierarchical cells determination process or attempt to resolve (e.g., remove) any cycle in the component-containment graph. Some insight is provided into how cycles can be formed in component-containment graphs as well as processes the hcell determination engine 110 may take to remove cycles.

The component-containment graph is constructed based on components of the class-correspondence graph, which in turn is formed based on determined identical-cell classes within a given circuit design and specified cell correspondence relationships between two different circuit designs. If these data structures are decomposed down to the level or granularity of individual cells, then three (3) kinds of links between individual cells can be identified: (1) two cells in the same circuit design can be understood as linked if the two cells are identical (e.g., as determined herein); (2) two cells in different circuit designs can be understood as linked if the two cells correspond to one other (e.g., as specified through the previously-determined corresponding hierarchical cells 140); and (3) two cells in the same circuit design can be understood as linked if one of the two cells includes one or more instances of the other of the two cells. These three types of links may form the set of possible link types that result in edges within a component-containment graph, and any given cycle in the component-containment graph can be decomposed or understood as a cycle in a finer-grained graph of individual cells connected by combinations edges via the three different links described above. Of these three edge types, containment-based edges may be in the form of directed edges, and identicality and correspondence-based edges may be bi-directional (or non-directional).

In order to break a cycle in the component-containment graph (e.g., as decomposed into a finer-grained graph at the individual-cell level), the hcell determination engine 110 may remove an edge along the path of the cycle. Note that a cycle can exist that passes through a subset of the three types of edges, which in turn can support classification of cycles into various types. As a first example, containment-edge only cycle may be a result of a circuit design's hierarchy and may result due to a circumstance in which a cell in the hierarchy contains instances of itself. This is an error in hierarchy of the circuit design itself. Responsive to a detection of a containment-edge only cycle, the hcell determination engine 110 may terminate the corresponding hierarchical cells determination process and outputting an error message indicative of the erroneous hierarchy. In some examples, the hcell determination engine 110 may not even encounter such an error during determination of additional corresponding hierarchical cells, and this type of cycle may be detected earlier in the LVS processes or EDA design flow, e.g., during construction of hierarchical circuit graphs in memory, during which an error message would be output and the erroneous hierarchy addressed.

As a second example, a cycle with a combination of containment and correspondence edges indicates a cycle in the combined hierarchical containment graph. Even without the corresponding hierarchical cells determination features described herein, such a cycle would still lead to an error condition and early termination of the LVS run. However, the hcell determination engine 110 can encounter this kind of cycle, for example if the hcell determination engine 110 determines additional hcell relationships prior to the point in the LVS process where such containment-correspondence type cycles are detected. As a third example, a cycle with all three kinds of edges is specific to the processing by the hcell determination engine 110. Such cycles may be referred to as containment-correspondence-identicality cycles. If such a cycle exists, an LVS process can still proceed to compare two circuits design, but the hcell determination engine 110 may need to resolve the cycle in order to topologically sort the component-containment graph.

The examples of cycles above indicate a hierarchical inconsistency in the source circuit design, the layout circuit design, both circuit designs, or the correspondence relationships specified between the two circuit designs. This is evident because both identicality and correspondence edges represent equivalence relations, and equivalence is transitive. Therefore, if there is a cycle, a given cell contains, directly or indirectly, instances of another cell that should be equivalent to the given cell, which is an absurdity. This suggests that a reasonable strategy for handling such cycles is for the hcell determination engine 110 to write out an error message and terminate the run. However, it turns out that there are some species of hierarchical inconsistency that are innocuous and well-defined.

Consider an example in which a component X can be decomposed into two identical-cell classes X1 (with a single cell A_{SRC}) and X2 (with a single cell B_{SRC}) from a source layout design and one identical cell class X3 from a layout circuit design (with cells A_{LYT} and B_{LYT}). In this example, a directed edge from A_{SRC} to B_{SRC} is present because cell A_{SRC} contains an instance of B_{SRC}. Also in this example, A_{SRC} corresponds to A_{LYT} and B_{SRC} corresponds to B_{LYT}. As can be understood, such a component would include a cycle within component X, e.g., in the form of a reflexive edge. This reflexive edge is induced by the fact that cell A_{SRC} contains instances of cell B_{SRC}, and both are in the same component X. A reflexive edge is always a cycle. But suppose layout cell A_{SRC} is a pass-through cell for B_{SRC}, e.g., A_{SRC} contains exactly one instance—an instance of B_{SRC}, and all of the ports of A_{SRC} are connected directly to, and only to, the corresponding pins of this instance of B_{SRC}. These two circuits cannot compare as LVS correct unless the instance of B_{SRC} is expanded into cell A_{SRC}.

Once the instance has been expanded, A_{SRC} and B_{SRC} on the source circuit design are now identical, and they might match A_{LYT} and B_{LYT} on the layout circuit design, leading to a correct result. But in this kind of case, typically the LVS comparison process will be configured to expand unbalanced instances, e.g., to expand hcell instances when corresponding cells have different instance counts in the cells of a higher-level pair of corresponding cells. In this example, the corresponding pair (A_{SRC}, A_{LYT}) contains instances of the corresponding pair (B_{SRC}, B_{LYT}), but the instance counts are unbalanced. As used herein, a “corresponding cell” may refer to a cell of a circuit design that is specified in one or more hcell correspondences. A_{SRC} contains one instance of B_{SRC} on the source circuit design-side, but A_{LYT} contains zero instances of B_{LYT} on the layout circuit design-side. Typically, this situation will result in the expansion of the instance of B_{SRC} into A_{SRC} in the source circuit design, and this removes the absurdity.

Although the example above results in a cycle in the component-containment graph, this type of well-defined circuit design can be nonetheless supported by the hcell determination engine 110. This kind of case can be supported by the hcell determination engine 110 because the pass-through containment of B_{SRC} in A_{SRC} on the source circuit design-side may be used as a shorthand way of expressing the identicality seen on the layout circuit design-side. Understood in this light, such a usage is not unreasonable. An EDA system user may be relying on unbalanced expansion to resolve what would otherwise be an absurdity, and the hcell determination engine 110 may support circuit designs that implement such formats of circuit design.

In theory, this special-case usage is limited to pass-through containment scenarios. But in practice, pass-through containment can end up looking more complex. For example, it might be the case that due to seed promotion in a circuit extraction step that cell A_{SRC} ends up containing some primitive devices along with the instance of cell B_{SRC}. These devices might, however, be unimportant to the end user for the purposes of LVS comparison, and an LVS process or other EDA design flow step might be configured to filter the primitive devices out in a later step. In such cases, the instance of B_{SRC} within A_{SRC} would still be intended as pass-through containment by the circuit designer. Because such cases exist, the capabilities of the hcell determination engine 110 may be robust in the face of cycles in the component-containment graph. Therefore, responsive to detection of a cycle during a topological sort, the hcell determination engine 110 may attempt to break the detected cycle. Of the three kinds of edges in the finer-grained graph described above, there are two edge types that the hcell determination engine 110 can remove—identicality edges and correspondence edges.

In order to break cycles in the component-containment graph, the hcell determination engine 110 may differentiate between different correspondence types specified between cells of a source circuit design and a layout circuit design. In doing so, the hcell determination engine 110 may classify the various correspondences specified in the previously-determined corresponding hierarchical cells 140 from which edges of the class-correspondence graph are induced, specified, inserted, or otherwise determined. The hcell determination engine 110 may classify user-specified correspondences or any correspondence directly configured by a user in the previously-determined corresponding hierarchical cells 140 as a hard hcell correspondence. For any cell correspondences automatically detected under program control in the previously-determined corresponding hierarchical cells 140 (e.g., via text matching), the hcell determination engine 110 may classify such cell correspondences as soft correspondences.

The hcell determination engine 110 may perform cycle breaking for a component-containment graph based on the type of correspondence (e.g., hard or soft) for correspondence edges in a cycle path. Responsive to a determination that a soft correspondence is part of a cycle path in the component-containment graph, the hcell determination engine 110 may consider the soft correspondence poorly-determined and attempt to resolve a hierarchical inconsistency causing the cycle by removing one or more edges induced through soft correspondences. As described herein, removing a soft correspondence (or any correspondence relationship) may alter the groupings of individual cell elements of the graph structures used herein. Rebuilding of the class-correspondence graph and component-containment graph after such removals may remove the previously-present cycles. In doing so, the hcell determination engine may process through individual cells across each individual component along the path of a cycle and identify any soft correspondences (e.g., edges thereof) within a given component that lie along any path through the given component to the next component in the cycle.

To make such an identification of soft correspondences, the hcell determination engine 110 may identify the input classes of the given component, which may refer to the identical-cell classes in which any cells of the given component are contained by cells in a previous component in the cycle path. Then, the hcell determination engine 110 may Identify the output classes of the given component, which may refer to the identical-cell classes in which any cells of the given component contain instances of cells in the next component in the cycle path. Responsive to a determination that an identical cell class in the given component is both an input class and an output class, then the hcell determination engine 110 may determine that are no correspondences in this given component that can be removed to break the cycle (though an exception may be determined for a reflexive cycle which can be broken even if a given component is both an input and output class). This may be the case as the cycle path through this given component would exist even if all correspondences in the component were removed. However, responsive to a determination that there are no identical cell classes in the given component that are both an input class and an output class, then the hcell determination engine 110 may determine the correspondences that lie along the paths from any input class to any output class. The hcell determination engine 10 may implement or apply any suitable graph processing algorithm or technique to do so, e.g., to exhaustively find paths from one set of vertices (e.g., input classes) in a graph to another (e.g., output classes).

The hcell determination engine 110 may apply the above steps for correspondence determinations for each component in a cycle path, and the set of determined correspondences among the various components in the cycle path may be referred to as a set of suspect correspondences. Note that if the hcell determination engine 110 were to remove all of the suspect correspondences between the cells of the source circuit design and layout circuit design, then the cycle would be broken. However, since there can exist parallel paths through a component in a cycle path, it is not guaranteed that removing any individual correspondence would break the cycle. Moreover, it is unclear which of the suspect correspondences may have been determined or specified in error.

There are several strategies that the hcell determination engine 110 may employ to attempt to break a cycle based on the detected suspect correspondences. As one example, the hcell determination engine 110 may use graph algorithms to search for a minimal set of correspondences meeting certain criteria that will break the cycle. As another example, the hcell determination engine 110 may choose a suspect correspondence arbitrarily or according to some heuristic, eliminate it, and then rebuild the graphs and determine whether the cycle still exists. The hcell determination engine 110 may repeat this process until the cycle is broken. As yet another example, the hcell determination engine 110 may remove all of the suspect correspondences, which is guaranteed to break the cycle, but may result in the loss of more correspondences than necessary. In some implementations, the hcell determination engine 110 may remove all suspect correspondences meeting certain criteria and then rebuild the graphs and determine whether the cycle still exists, repeating as necessary. These examples are not comprehensive and the hcell determination engine 110 may implement any suitable cycle-breaking technique consistent with the features described herein.

In some implementations, the hcell determination engine 110 may remove any soft correspondences from among the suspect correspondences (which may include a combination of hard and soft correspondences). Then, the hcell determination engine 110 may rebuild the class-correspondence and component-containment graphs to determine whether the cycle has been removed or not. If the cycle has been removed, the hcell determination engine 110 can proceed. If not, then the hcell determination engine 110 may take further action.

If the hcell determination engine 110 finds no soft correspondences among the suspect correspondences for a cycle path (e.g., after removal of all soft correspondences and cycles still exist), the hcell determination engine 110 may next try to break the cycle by removing identicality relationships. The hcell determination engine 110 may use similar method as that used to find suspect correspondences. That is, the hcell determination engine 110 can determine, within components in the cycle path, a set of identicality relationships to remove that will break the cycle. To do so, the hcell determination engine 110 may identify, for a given component, input cells in the given component, which may refer to any cells in the given component that contained by any cell in the previous component of the cycle path. The hcell determination engine 110 may also identify output cells in the given component, which may refer to any cells of the given component that contain any cell in the next component of the cycle path. Responsive to a determination that an input cell or any cell that corresponds with an input cell is an output cell, the hcell determination engine 110 may determine that the cycle cannot be broken by removing identicality relationships in this given component. The hcell determination engine 110 may make a special exception to this criterion for reflexive cycles, for which this rule does not apply. However, responsive to a determination that no input cell and no cell that corresponds with an input cell is an output cell, the hcell determination engine 110 can ascertain that the cycle is guaranteed breakable by removing one or more identicality relationships in this given component. If the cycle can be broken in the given component, the hcell determination engine 110 may remove identicality relationships from the given component to break the cycle, particularly along each path from any input cell or any cell that corresponds with an input cell to any output cell.

This step by the hcell determination engine 110 may be implemented or performed via complex graph algorithms. As a shortcut to doing the graph processing, that step can be replaced by noting that if all input cells and cells they correspond with are removed from any nontrivial identicality classes they may be part of, the cycle will be broken. This latter approach by the hcell determination engine 110 may remove cells from some identicality classes unnecessarily, but it will break the cycle. Since this kind of cycle is expected to be rare, and the only upshot of unnecessarily breaking up identicality classes is that the hcell determination engine 110 may fail to detect some hcells could have been added, some implementation examples take this approach. As with breaking the cycle using suspect correspondences, there are several other potential strategies that fall within the purview of the corresponding hierarchical cells determination technology of the present disclosure, which involve various implementation trade-offs.

In removing cycles from the component-containment graph, it may be beneficial to dissolve as few identicality relationships as possible. As components in a cycle path may have a different number of identicality relationships that need to be dissolved to eliminate the cycle, the hcell determination engine 110 may identify the component where the cycle can be broken by removing the smallest number of identicality relationships and break the cycle via this component. After a cycle is broken using this method, the hcell determination engine 110 can rebuild the class-correspondence and component-containment graphs, now with the cycle removed. Note that there can be multiple cycles in a component-containment graph, and some current topological sort methods detect one at a time. If this is the case, the hcell determination engine 110 may repeat the cycle-breaking processes described herein as necessary to obtain a topologically-sorted component-containment graph. Implementations are possible that detect and deal with all cycles in a single step as well.

Note that it is possible to reach this point and the hcell determination engine 110 determine that no component in the cycle path has either soft correspondences or identicality relationships that can be removed to break the cycle. In that case, the cycle exists in the combined hierarchical containment graph. When the hcell determination engine 110 encounters such a cycle, some implementations cause an error-message write-out. Such a message can list the suspect correspondences along the path of the cycle. Then the additional corresponding hierarchical cells determination process may terminate, and the LVS process can continue with the expectation that the cycle will be detected in a later step, leading to an error and early termination of the LVS process without comparing the circuits. Other implementations are possible that use other approaches. For example, an implementation may attempt to correct a cycle by eliminating hard correspondences, or by expanding some containment relationships in the circuit graphs.

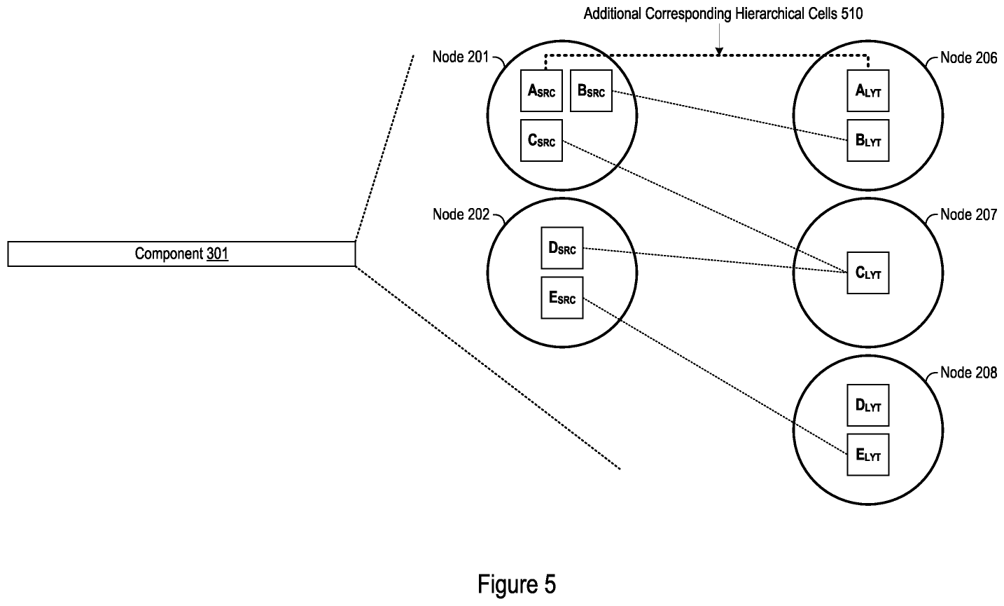

In any of the various ways described herein, individually or in combination, the hcell determination engine 110 may topologically sort a component-containment graph, which may include breaking one or more cycles in the component-containment graph to obtain a valid topological sort. Once the hcell determination engine 110 generates a component-containment graph without cycles and with a valid topological ordering of the graph components, the additional corresponding hierarchical cells determination process can continue. As part of a next step, the hcell determination engine 110 may process the components of the sorted component-containment graph in a top-down order. Example features of processing components to determine additional corresponding hierarchical cells are described next with reference to FIG. 5.

FIG. 5 shows an example processing of a component to determine additional corresponding hierarchical cells. While FIG. 5 shows an example processing of a single component (e.g., component 301), the hcell determination processing engine 110 may process some or all of the components in the component-containment graph. In some examples, the hcell determination engine 110 may, prior to processing, discard any trivial components, as such components may not include any suitable candidates for additional correspondences.

As part of (or separate to) the processing of components of a component-containment graph, the hcell determination engine 110 may compute instance-containment metrics. Such instance-containment metrics may be used in heuristics when the hcell determination engine 110 considers candidates for additional corresponding hierarchical cells. Implementations are possible in which instance-containment metrics are computed by the hcell determination engine 110 at other points in the process, including computing the metrics on demand as required. In some implementations, the hcell determination engine 110 computes initial metrics up-front after topologically sorting the component-containment graph.

As described subsequently, some of the heuristics applied by the hcell determination engine 110 may be based on balanced hierarchical instance counts in containing corresponding cell pairs for the two circuit designs. In order to make such kinds of heuristic determinations when considering candidate additional correspondences, the hcell determination engine 110 may require a hierarchical instance count of each cell that might be part of the candidate correspondence to be evaluated.

To further explain the concept of hierarchical instance counts, note that after hcell correspondences are identified, prior to circuit comparison, the LVS process may flatten cells that are not in an hcell correspondence. Hierarchical instance counts are generally the instance counts as they will be after this flattening occurs, but with certain exceptions. Suppose cell A_{SRC} of a source circuit design is in an hcell correspondence, and that cell A_{SRC} contains two instances of B_{SRC}, which is not in an hcell correspondence. After flattening, A_{SRC} will contain no instances of B_{SRC}, but it will contain two copies of all the contents of B_{SRC}. In regard to hierarchical instance counts, however, the hcell determination engine 110 may keep track that A_{SRC} contains two instances of B_{SRC}, in addition to A_{SRC} containing two copies of B's contents. The reason for this is so the hcell determination engine 110 can consider what the hierarchical instance counts of noncorresponding cells will be if the hcell determination engine 110 later determines to add such noncorresponding cells as additional corresponding hierarchical cells. As used herein, a noncorresponding cell may refer to a cell that is not specified as part of any hcell correspondence. If the hcell determination engine 110 later determines that cell B_{SRC} should be added to an additional correspondence, the hcell determination engine 110 can track that A_{SRC} will then contain two instances of B_{SRC}. This allows the hcell determination engine 110 to check whether the resulting correspondence will be balanced in the corresponding pair or pairs that A_{SRC} is a part of. This double accounting does not affect the accuracy of the counts. In all containing corresponding cells, the hcell determination engine 110 can accurately track the counts of lower-level corresponding cells, and the hcell determination engine 110 can accurately track the counts of noncorresponding cells that will be flattened, alongside counts of their contents as if they had been flattened.

As used herein, a hierarchical instance count may refer to a nonnegative integer that relates to two cells—namely, it may refer to a count of instances of a given cell contained within another cell. The hcell determination engine 110 may use hierarchical instance counts for two purposes: (1) to evaluate potential hcell additions based on instance-count balances in the two circuit designs, and (2) to update the calculated hierarchical instance counts incrementally when a new hcell correspondence is added. For the first purpose, the hcell determination engine 110 may need only the hierarchical instance counts in corresponding cells, because balance checks are only possible in corresponding pairs. For the second purpose, the hcell determination engine 110 may require the hierarchical instance counts in all noncorresponding cells that might be added to correspondences.

Note that for the first purpose, the hcell determination engine 110 may require only the hierarchical instance counts of candidate cells that could end up either added to additional correspondences or in correspondences with cells that have been added in additional correspondences. These cells may be referred to as cells-of-interest. For the second purpose, the hcell determination engine 110 may require only the hierarchical instance counts of cells that need to be maintained for the first purpose, that is, cells-of-interest. Therefore, the hcell determination engine 110 can limit the scope of calculations to cells-of-interest in order to improve computational efficiency. Determination of cells-of-interest is described in greater detail herein.

The hcell determination engine 110 may calculate hierarchical instance counts in a bottom-up topological order based on containment. In such an order, upon reaching a given cell, the hierarchical instance counts of all cells it contains instances of have already been calculated, which can allow for propagating of instance counts of the contents of noncorresponding cells upward as the processing progresses. Observe that the topological ordering of the components of the component-containment graph provides a topological ordering of cells, as follows. Since there are no cycles in the graph, and edges are induced by containment, it follows that no cell in a component contains instances of any other cell in the same component, directly or indirectly. This entails that all cells in a given component are at the same topological level. And in the top-down ordering of components, each component appears before all components that any of its cells contain instances of. Therefore, the hcell determination engine 100 can process through the components (prior to discarding the trivial ones) in top-down topological order, and assign every cell an ordinal in a topological ordering of cells, choosing contiguous or identical ordinals for all the cells within each component. Sorting the cells in the reverse order of these ordinals yields a bottom-up ordering.

The mechanism by which the hcell determination engine 110 may calculate the initial hierarchical instance counts may be any suitable process, algorithm, or technique. Many such algorithms are possible with different characteristics, and the hcell determination engine 110 may implement any such capability. Note that the hcell determination engine 110 may calculate the hierarchical instance count of each cell-of-interest in each corresponding cell of a candidate additional correspondence (e.g., in the form of “combinations” as described herein) as well as in each non-corresponding cell-of-interest (e.g., not part of a correspondence). Note that the combination generation capabilities of the hcell determination engine 110 are described further herein, which can include potential cell correspondences to be considered for viability. Here, note that the hcell determination engine 110 can identify cells-of-interest by generating the combinations that will be considered for additional hcell correspondences and by mark cells that occur in such combinations as cells-of-interest.

Note also that it is common in LVS verification to perform various transformations on the circuits to be compared between the time when hcell correspondences are formed and when comparison is performed. The heuristics of the present disclosure can be made more accurate by taking these transformations into account, e.g., by computing hierarchical instance counts as they will exist in the transformed circuits. A particularly important case, which has already been mentioned, is expanding instances of unbalanced hcells. Computing hierarchical instance counts in such a way as to account for this expansion adds complexity to the process, while improving the quality of heuristics. Such computational nuances are within the purview of the corresponding hierarchical cells determination technology described herein.

In addition to hierarchical instance counts, the hcell determination engine 110 may generate a collection for each cell-of-interest that comprises any corresponding cells or correspondence relationships that contains instances of the cell-of-interest, whether directly or indirectly. These corresponding cells may be referred to as parent hcells. Such collections (also referred as parent lists) can be built by the hcell determination engine 110 based on the hierarchical instance counts simply by going through the hierarchical instance counts in each corresponding cell and adding that corresponding cell to each of its contained cell's collection. Since the hcell determination engine 110 need only calculate hierarchical instance counts of cells-of-interest, then only cells-of-interest will end up with collections.

As noted herein, the hcell determination engine 110 may determine that any additional hcell correspondences be formed among cells within the same connected component of the class-correspondence graph. This may be the case as cells in each component are, in a sense, equivalent. Thus, it would be reasonable to form correspondences between such cells of the same component. For any potential additional corresponding hierarchical cells to be considered, the hcell determination engine 110 may employ heuristics to determine whether the correspondence appears viable. These heuristics may be based on instance-containment metrics, e.g., as initially computed as described previously. The addition of an additional corresponding hierarchical cells relationship, however, can change the instance-containment metrics that the applied heuristics rely on. Thus, the hcell determination engine 110 may ensure that when an additional cell correspondence is determined, the addition does not invalidate choices that have already been made.

To elaborate further, consider how adding an additional correspondence changes hierarchical instance counts. Suppose some corresponding cell A_{SRC} in the source circuit design contains an instance of noncorresponding cell B_{SRC}. Since B_{SRC} does not correspond, it is designated to be flattened during the LVS comparison process. As such, the hierarchical instance counts in A_{SRC} reflect the contents of B_{SRC}, recursively down to the level of corresponding cells. That is, B_{SRC} contains instances of noncorresponding cell C_{SRC}, then the contents of C_{SRC} will be flattened into B_{SRC}, which will be flattened into A_{SRC}. The hcell determination engine 110 may ensure that the hierarchical instance counts of A_{SRC} reflect as such. However, if B_{SRC} contains instances of corresponding cell D_{SRC}, then contents of D_{SRC} will not be flattened into B_{SRC}. In such a situation, the hierarchical instance counts of A_{SRC} will reflect instances of D_{SRC} only, though not the contents of cell D_{SRC}.

In this illustration, if B_{SRC} is determined be part of an additional correspondence by the additional hierarchical cells determination process, then B_{SRC} will no longer be designated for flattening. Hence, the counts of the contents of B_{SRC} must be subtracted out of the hierarchical instance counts in A_{SRC}, once per each instance of B_{SRC} in A_{SRC}. From this illustration, it can be noted that determining a given cell B_{SRC} as a corresponding cell affects the hierarchical instance counts in cells that contain instances of B_{SRC}, and it affects hierarchical instance counts of cells-of-interest that B_{SRC} contains instances of, directly or indirectly. Counts of cells that come after B_{SRC} in a top-down topological ordering can change in the cells that come before B_{SRC} in a top-down topological ordering. When considering a potential new hcell correspondences in a given component, the hcell determination engine 110 may interact, consider, or alter hierarchical instance counts of the cells in that given component. By processing the components in a top-down topological order, the hcell determination engine 110 can ensure that any changes to the hierarchical instance counts of cells in a given component have already occurred prior to the processing of the given component, thus ensuring accuracy through the top-down processing order.

The hcell determination engine 110 may thus process components in a top-down order. In the example of FIG. 5, the hcell determination engine 110 processes the component 301 and determines an additional correspondence as the additional corresponding hierarchical cells 510 shown in FIG. 5. Then, the hcell determination engine 110 may process a next component in the top-down order, and continue until the process completes. The processing by the hcell determination engine 110 of a given component may include the following steps: (1) generate combinations; (2) evaluate and rank combinations; (3) select combinations to implement; and (4) implement the selected combinations as additional corresponding hierarchical cells. Each of these steps are described in turn.

With regards to combination generation, a combination may refer to any candidate correspondence between cells of two circuit designs. Combinations may be one-to-one or many-to-one. In a many-to-one combination, a single cell of a circuit design (e.g., the source circuit design 120) is grouped with multiple cells of the other circuit design (e.g., the layout circuit design 130). The hcell determination engine 110 may determine additional cell correspondences by choosing combinations to implement. When a combination is implemented, the hcell determination engine 110 may establish a one-to-one or many-to-one correspondence among the cells of the combination.

The hcell determination engine 110 may generate a combination such that the cells in the combination are in the same component and at least one of the cells is currently not in any cell correspondence. In a one-to-one combination, the hcell determination engine 110 may select cells that are both currently noncorresponding. In a many-to-one combination, the hcell determination engine 110 may generate the combination such that either all of the cells are currently noncorresponding or the cell on the “one” side is already in one or more correspondences, in which case the cells on the “many” side will include those that the “one” cell already corresponds with, along with one or more additional noncorresponding cells.

The hcell determination engine 110 may utilize any existing or suitable algorithms that can generate all possible combinations among the cells in a component. However, since the number of possible combinations for a given component grows exponentially based on the greatest number of noncorresponding cells for one of the circuit designs of the component, the hcell determination engine 110 may employ limits and generate only a subset of the possible combinations. Doing so may bound the run-time and memory requirements of the solution. In some implementations, the hcell determination engine 110 employs a fixed threshold. When the greatest number of noncorresponding cells in a circuit design for the given component surpasses the fixed threshold, only combinations that include either a single noncorresponding cell or all noncorresponding cells in a circuit design may be generated by the hcell determination engine 110 for the given component. Many other schemes are possible, and all are within the purview of this disclosure. In such a manner, the hcell determination engine 110 may generate combinations for a given component that satisfy the criteria above.

Next, the hcell determination engine may evaluate and rank the generate combinations. The hcell determination engine 110 may evaluate each combination and assign a rank, which can be called a viability rank. This is the point in which the hcell determination engine 110 may apply heuristics based on instance-containment metrics. Combinations that are not deemed viable will not be considered further. Viable combinations will have precedence for consideration.

In some implementations, the hcell determination engine 110 ranks combinations through three different viability ranks, for example the first viability rank as the strongest (e.g., greatest weight) and the third viability rank as the weakest (e.g., lowest weight).

As a first viability rank, the hcell determination engine 110 may consider whether or not the combination is balanced in every corresponding pair that contains instances of any of the cells of the combination. If any combination satisfies this criteria for the first viability rank, then the hcell determination engine 110 may rank the combination with this first viability rank.

As second viability rank, the hcell determination engine 110 may consider whether or not the combination is balanced in every one-to-one correspondence that contains instances of any of the cells of the combination. For this second viability rank, the hcell determination engine 110 may apply the following additional criteria: (A) For each many-to-one correspondence that contains instances of any of the combination cells of the combination, the following conditions hold: (1) The “one”-side cell contains at least one instance of a cell in the combination, and (2) The combination is balanced in at least one corresponding pair in the many-to-one correspondence; (B) At least three existing corresponding pairs contain instances of cells in this combination, and it is balanced in greater than half of the pairs that contain instances of it; (C) There is at least one containing correspondence where the combination is balanced in all pairs of that correspondence. (This containing correspondence may be one-to-one.); (D) If the combination is many-to-one, for each cell on its “many” side there is at least one existing corresponding pair containing that cell in which the combination is balanced; and (E) If the combination includes any currently corresponding cells, the combination with all its cells is balanced in more of its containing corresponding pairs than the original correspondence with only the combination's corresponding cells. Combinations, additional, or alternative criteria as described above may be applied by the hcell determination engine 110 for viability rank determinations.

As a third viability rank, the hcell determination engine 110 may consider whether the combination may be balanced or unbalanced in any corresponding pair that contains it, but additional criteria B through E for the second viability rank are met. Responsive to a determination that the criteria above are not met for any of the defined levels of viability rank, then the hcell determination engine 110 may rank the combination as not viable, and no longer consider the combination as a candidate for an additional correspondence for the two circuit designs.

In the criteria specified above for viability rank determinations, the hcell determination engine 110 may apply a defined metric for balance determinations. For example, the hcell determination engine 110 may determine a combination as balanced within a containing corresponding pair if the sum of the hierarchical instance counts of all the combination's cells within the containing pair's source cell equals the sum of the hierarchical instance counts of all the combination's cells within the containing pair's layout cell. In some implementations, the hcell determination engine 110 may use precalculated parent lists to determine which correspondences contain each cell in a combination, and the hcell determination engine 110 can use precalculated hierarchical instance counts to determine in which containing pairs the combination is balanced. Other implementations are possible. Likewise, the heuristics defined above should be considered part the disclosed corresponding hierarchical cells determination technology, but any suitable heuristics can be applied for additional correspondence determinations. Nor is the corresponding hierarchical cells determination technology limited to heuristics based solely on instance-containment metrics. Other types of data may be considered by heuristics, such as cell names.

In general, the hcell determination engine 110 may apply heuristics so as to avoid, as far as possible, adding correspondences between cells that do not actually correspond. At the same time, the hcell determination engine 110 may apply heuristics and techniques that remain robust in cases where the automatic expansion of certain unbalanced instances can correct correspondence problems, as well as in cases where there may yet be discrepancies between the circuit designs being compared.

In a next processing step, the hcell determination engine 110 may select which combinations to implement. After the generated combinations in a component have been evaluated and ranked for viability, the hcell determination engine 110 may next choose which combinations, if any, to implement by adding as new hcell correspondences. In some implementations, the hcell determination engine 110 may apply a general rule that among the combinations selected to implement, no cell may appear more than once. If the hcell determination engine 110 fails to observe this rule, it may result in the creation of additional correspondences that do not actually meet the viability criteria or that include many-to-many relationships. The hcell determination engine 110 may have evaluated each combination as to encompass the full extent of correspondence between all the cells in the combination. Such an evaluation should be upheld by the hcell determination engine 110 in selection of combinations to implement.

Thus, if two combinations ranked as viable by the hcell determination engine 110 contain the same cell, one or both of them must be discarded. To do so, the hcell determination engine 110 may apply the following criteria and processing steps. If the two combinations containing the same cell have different viability rank values, the hcell determination engine 110 may discard the combination among the two with the lower degree of viability. If the two combinations have the same viability rank value, the hcell determination engine 110 may discard both combinations. The rationale behind such processing is that, if the viability ranks are different, one of the two combinations is a stronger candidate. Otherwise, the two combinations are ambiguous, e.g., neither is clearly a better choice than the other, and yet only one of them can be the correct choice. Unable to make a clear distinction as to which is correct, the hcell determination engine 110 may discard both. After combinations have been discarded according to these rules, the hcell determination engine 110 may ensure that no cell appears in more than one of the remaining set of viable combinations (if any), so the remaining combinations can be selected by the hcell determination engine 110 for implementation as additional corresponding hierarchical cells.

Next, the hcell determination engine 110 may implement the selected combinations as additional corresponding hierarchical cells between a source circuit design and a layout circuit design. In some examples, the hcell determination engine 110 can factor a given combination into cell pairs, wherein each pair contains one cell from each circuit design. If the combination is a one-to-one type, there is only one such pair. If the combination is many-to-one, there is one such pair for each cell on the “many” side, in which that cell is paired with the one and only cell on the “one” side. To implement a chosen combination, the hcell determination engine 110 can factor a given combination into pairs, and for each pair that includes one or two noncorresponding cells, the hcell determination engine 110 establishes an additional correspondence as the correspondence between the cells of the pair. The hcell determination engine 110 may also calculate updated hierarchical instance counts and update collections/parent lists based on the conversion of one or both cells in the pair from noncorresponding cell(s) to corresponding cell(s).

The hcell determination engine 110 may update hierarchical instance counts as follows. Suppose some cell A_{SRC} is transitioning from being a noncorresponding cell to a corresponding cell as part of implementation of a selected combination. This entails that A_{SRC} may be no longer designated for flattening prior to a hierarchical LVS comparison. In every corresponding cell C_{SRC} (that is a cell in a correspondence) that contains instances of A_{SRC}, the hierarchical instance counts will include the contents of A_{SRC}, that is counts for cell A_{SRC} for contained cells-of-interest multiplied by the number of instances of A_{SRC} in C_{SRC}. Updating of these counts in C_{SRC} by the hcell determination engine 110 may require reversing them by subtraction. Each count of some cell-of-interest B_{SRC} contained directly or indirectly in A_{SRC} must be multiplied by the number of instances of A_{SRC} in C_{SRC}, and the result of this multiplication must be subtracted from the count of B_{SRC} in C_{SRC}. Updating the hierarchical instance counts for the conversion of A_{SRC} to a corresponding cell entails making these corrections in every corresponding cell that contains instances of A_{SRC}.

The hcell determination engine 110 may already maintain hierarchical instance counts in the cell-of-interest A_{SRC} that is becoming a corresponding cell. Such hierarchical instance counts can only change if and when some noncorresponding cell that A_{SRC} contains becomes a corresponding cell. However, since the hcell determination engine processes the components in a top-down ordering, it can be known that the instance counts for A_{SRC} have not had opportunity to change since initially computed. Therefore, once A_{SRC} has been made into a corresponding cell by the hcell determination engine 110, the counts of cells it contains, directly or indirectly, are already correct.

The scheme described here of initially calculating hierarchical instance counts and maintaining them as new corresponding cells are added can be implemented in various ways. Other schemes are possible and within the purview of the technology of the present disclosure. Also, if circuit transformations such as unbalanced expansion are accounted for in the calculations, more complex algorithms may be required, which are also covered by the technology described herein. As an algorithmic convenience, in some implementations, the hcell determination engine 110 may maintain parent lists as described previously. Converting a noncorresponding cell to a corresponding cell can cause the hcell determination engine 110 to update parent lists in two ways: (1) The newly corresponding cell becomes a parent to all the cells-of-interest it contains instances of, directly or indirectly, and (2) The count updates can result in instance counts dropping to zero in a containing cell, in which case that containing cell is no longer a parent to the contained cell whose instance count is now zero.

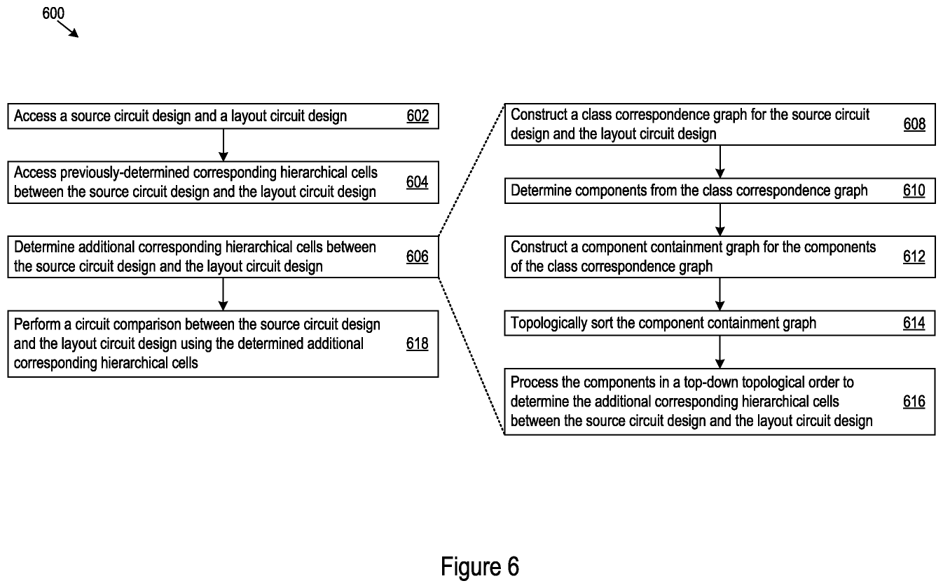

FIG. 6 shows an example of logic 600 that a system may implement to support improved determinations of corresponding hierarchical cells between circuit designs according to the present disclosure. For example, the computing system 100 may implement the logic 600 as hardware, executable instructions stored on a machine-readable medium, or as a combination of both. The computing system 100 may implement the logic 600 via the hcell determination engine 110, through which the computing system 100 may perform or execute the logic 600 as a method to support corresponding hierarchical cells determinations. The following description of the logic 600 is provided using the hcell determination engine 110 as an example implementation. However, other implementation options by computing systems are possible.

In implementing the logic 600, the hcell determination engine 110 may access a source circuit design and a layout circuit design (602) as well as access previously-determined corresponding hierarchical cells between the source circuit design and the layout circuit design (604). In implementing the logic 600, the hcell determination engine 110 may also determine additional corresponding hierarchical cells between the source circuit design and the layout circuit design (606), including by: constructing a class-correspondence graph for the source circuit design and the layout circuit design (608), determining components from the class-correspondence graph (610), wherein each component in the class-correspondence graph is a disjointed sub-graph in the class-correspondence graph, constructing a component-containment graph for the components of the class-correspondence graph (612), topologically sorting the component-containment graph (614), and processing the components in a top-down topological order to determine the additional corresponding hierarchical cells between the source circuit design and the layout circuit design (616), doing so in any of the ways described herein. In implementing the logic 600, the hcell determination engine 110 may further perform a circuit comparison between the source circuit design and the layout circuit design using the determined additional corresponding hierarchical cells (618), doing so by implementing or performing any suitable circuit comparison technology (e.g., LVS comparison processes).

The logic 600 shown in FIG. 6 provides an illustrative example by which a computing system 100 may support or implement various features of the corresponding hierarchical cells determination technology described herein. Additional or alternative steps in the logic 600 are contemplated herein, including according to any of the various features described herein for the hcell determination engine 110.

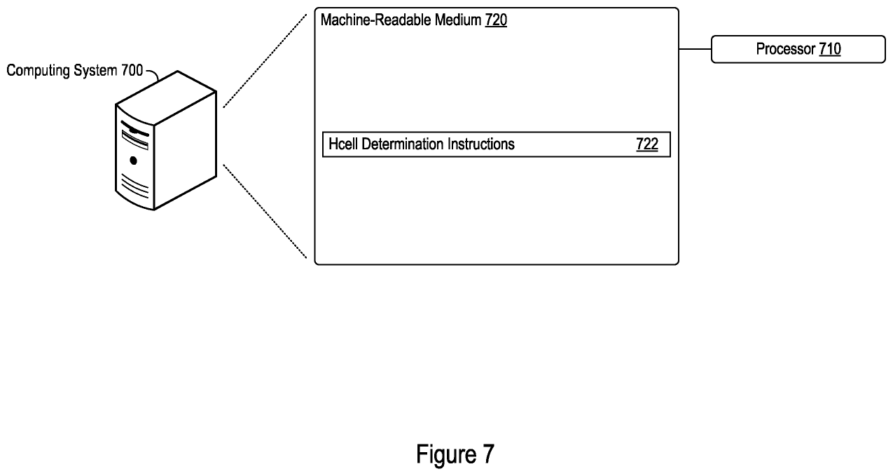

FIG. 7 shows an example of a computing system 700 that supports improved determinations of corresponding hierarchical cells between circuit designs according to the present disclosure. The computing system 700 may include a processor 710, which may take the form of a single or multiple processors. The processor(s) 710 may include a central processing unit (CPU), microprocessor, or any hardware device suitable for executing instructions stored on a machine-readable medium. The computing system 700 may include a machine-readable medium 720. The machine-readable medium 720 may take the form of any non-transitory electronic, magnetic, optical, or other physical storage device that stores executable instructions, such as the hcell determination instructions 722 shown in FIG. 7. As such, the machine-readable medium 720 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 700 may execute instructions stored on the machine-readable medium 720 through the processor 710. Executing the instructions (e.g., the hcell determination instructions 722) may cause the computing system 700 to perform or implement any of the corresponding hierarchical cells determination technology described herein, including according to any aspect of the hcell determination engine 110.

For example, execution of the hcell determination instructions 722 by the processor 710 may cause the computing system 700 to access a source circuit design and a layout circuit design as well as access previously-determined corresponding hierarchical cells between the source circuit design and the layout circuit design. Execution of the hcell determination instructions 722 by the processor 710 may also cause the computing system 700 to determine additional corresponding hierarchical cells between the source circuit design and the layout circuit design, including by: constructing a class-correspondence graph for the source circuit design and the layout circuit design, determining components from the class-correspondence graph, wherein each component in the class-correspondence graph is a disjointed sub-graph in the class-correspondence graph, constructing a component-containment graph for the components of the class-correspondence graph, topologically sorting the component-containment graph, and processing the components in a top-down topological order to determine the additional corresponding hierarchical cells between the source circuit design and the layout circuit design, doing so in any of the ways described herein. Execution of the hcell determination instructions 722 by the processor 710 may further cause the computing system 700 to perform a circuit comparison between the source circuit design and the layout circuit design using the determined additional corresponding hierarchical cells.

Any combination of the corresponding hierarchical cells determination technology as described herein may be implemented via the hcell determination instructions 722.

The systems, methods, devices, and logic described above, including the hcell determination engine 110, may be implemented in many different ways in many different combinations of hardware, logic, circuitry, and executable instructions stored on a machine-readable medium. For example, the hcell determination engine 110, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the hcell determination engine 110.

The processing capability of the systems, devices, and engines described herein, including the hcell determination engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples and features have been described above, many more implementations are possible.

1. A method comprising:
by a computing system:
accessing a source circuit design and a layout circuit design;
accessing previously-determined corresponding hierarchical cells between the source circuit design and the layout circuit design;
determining additional corresponding hierarchical cells between the source circuit design and the layout circuit design, including by:
constructing a class-correspondence graph for the source circuit design and the layout circuit design, wherein a given node in the class-correspondence graph represents a set of identical cells in the source circuit design or a set of identical cells in the layout circuit design, and wherein edges between nodes in the class-correspondence graph are specified based on the previously-determined corresponding hierarchical cells;
determining components from the class-correspondence graph, wherein each component in the class-correspondence graph is a disjointed sub-graph in the class-correspondence graph;
constructing a component-containment graph for the components of the class-correspondence, wherein each node in the component-containment graph represents a component from the class-correspondence graph and directed edges in the component-containment graph specify that a given cell in a given component contains an instance of another cell from another component;
topologically sorting the component-containment graph; and
processing the components in a top-down topological order to determine the additional corresponding hierarchical cells between the source circuit design and the layout circuit design; and
performing a circuit comparison between the source circuit design and the layout circuit design using the determined additional corresponding hierarchical cells.

2. The method of claim 1, wherein processing a given component to determine the additional corresponding hierarchical cells comprises:
generating combinations for the given component, wherein a combination comprises at least one cell of the source circuit design and at least one cell of the layout circuit design; and
implementing one or more of the combinations as the additional corresponding hierarchical cells.

3. The method of claim 2, wherein processing the given component to determine the additional corresponding hierarchical cells further comprises evaluating the combinations based on viability ranks, including a viability rank that assesses whether or not a given combination is balanced in other corresponding hierarchical cells that contains instances of any cells of the given combination.

4. The method of claim 2, wherein processing the given component to determine the additional corresponding hierarchical cells further comprises:
detecting that two of the combinations include a same cell; and
discarding one or both of the combinations.

5. The method of claim 1, further comprising discarding trivial components prior to or during processing of the components,
wherein a trivial component contains no nontrivial classes or contains a single nontrivial class, and
wherein a nontrivial class is an identical-cell class which includes multiple cells.

6. The method of claim 1, wherein topologically sorting the component-containment graph comprises:
identifying a cycle in the component-containment graph; and
breaking the cycle in the component-containment graph by removing an edge induced by a corresponding relationship between cells in the source layout design and the circuit layout design, removing an edge induced by an identicality relationship between cells in the source layout design and the circuit layout design, or a combination of both.

7. The method of claim 1, wherein constructing a class-correspondence graph for the source circuit design and the layout circuit design comprises:
identifying identical-cell classes among cells of the layout circuit design based on identicality criteria; and
identifying identical-cell classes among cells of the source circuit design based on the identicality criteria.

8. A system comprising:
a processor; and
a non-transitory machine-readable medium comprising instructions that, when executed by the processor, cause a computing system to:
access a source circuit design and a layout circuit design;
access previously-determined corresponding hierarchical cells between the source circuit design and the layout circuit design;
determine additional corresponding hierarchical cells between the source circuit design and the layout circuit design, including by:
constructing a class-correspondence graph for the source circuit design and the layout circuit design, wherein a given node in the class-correspondence graph represents a set of identical cells in the source circuit design or a set of identical cells in the layout circuit design, and wherein edges between nodes in the class-correspondence graph are specified based on the previously-determined corresponding hierarchical cells;
determining components from the class-correspondence graph, wherein each component in the class-correspondence graph is a disjointed sub-graph in the class-correspondence graph;
constructing a component-containment graph for the components of the class-correspondence graph, wherein each node in the component-containment graph represents a component from the class-correspondence graph and directed edges in the component-containment graph specify that a given cell in a given component contains an instance of another cell from another component;
topologically sorting the component-containment graph; and
processing the components in a top-down topological order to determine the additional corresponding hierarchical cells between the source circuit design and the layout circuit design; and
perform a circuit comparison between the source circuit design and the layout circuit design using the determined additional corresponding hierarchical cells.

9. The system of claim 8, wherein the instructions cause the computing system to process a given component to determine the additional corresponding hierarchical cells by:
generating combinations for the given component, wherein a combination comprises at least one cell of the source circuit design and at least one cell of the layout circuit design; and
implementing one or more of the combinations as the additional corresponding hierarchical cells.

10. The system of claim 9, wherein the instructions cause the computing system to process the given component to determine the additional corresponding hierarchical cells further by evaluating the combinations based on viability ranks, including a viability rank that assesses whether or not a given combination is balanced in other corresponding hierarchical cells that contains instances of any cells of the given combination.

11. The system of claim 9, wherein the instructions cause the computing system to process the given component to determine the additional corresponding hierarchical cells further by:
detecting that two of the combinations include a same cell; and
discarding one or both of the combinations.

12. The system of claim 8, wherein the instructions further cause the computing system to discard trivial components prior to or during processing of the components,
wherein a trivial component contains no nontrivial classes or contains a single nontrivial class, and
wherein a nontrivial class is an identical-cell class which includes multiple cells.

13. The system of claim 8, wherein the instructions cause the computing system to topologically sort the component-containment graph by:
identifying a cycle in the component-containment graph; and
breaking the cycle in the component-containment graph by removing an edge induced by a corresponding relationship between cells in the source layout design and the circuit layout design, removing an edge induced by an identicality relationship between cells in the source layout design and the circuit layout design, or a combination of both.

14. The system of claim 8, wherein the instructions cause the computing system to construct a class-correspondence graph for the source circuit design and the layout circuit design by:
identifying identical-cell classes among cells of the layout circuit design based on identicality criteria; and
identifying identical-cell classes among cells of the source circuit design based on the identicality criteria.

15. A non-transitory machine-readable medium comprising instructions that, when executed by the processor, cause a computing system to:
access a source circuit design and a layout circuit design;
access previously-determined corresponding hierarchical cells between the source circuit design and the layout circuit design;
determine additional corresponding hierarchical cells between the source circuit design and the layout circuit design, including by:
constructing a class-correspondence graph for the source circuit design and the layout circuit design, wherein a given node in the class-correspondence graph represents a set of identical cells in the source circuit design or a set of identical cells in the layout circuit design, and wherein edges between nodes in the class-correspondence graph are specified based on the previously-determined corresponding hierarchical cells;
determining components from the class-correspondence graph, wherein each component in the class-correspondence graph is a disjointed sub-graph in the class-correspondence graph;
constructing a component-containment graph for the components of the class-correspondence graph, wherein each node in the component-containment graph represents a component from the class-correspondence graph and directed edges in the component-containment graph specify that a given cell in a given component contains an instance of another cell from another component;
topologically sorting the component-containment graph; and
processing the components in a top-down topological order to determine the additional corresponding hierarchical cells between the source circuit design and the layout circuit design; and
perform a circuit comparison between the source circuit design and the layout circuit design using the determined additional corresponding hierarchical cells.

16. The non-transitory machine-readable medium of claim 15, wherein the instructions cause the computing system to process a given component to determine the additional corresponding hierarchical cells by:
generating combinations for the given component, wherein a combination comprises at least one cell of the source circuit design and at least one cell of the layout circuit design; and
implementing one or more of the combinations as the additional corresponding hierarchical cells.

17. The non-transitory machine-readable medium of claim 16, wherein the instructions cause the computing system to process the given component to determine the additional corresponding hierarchical cells further by evaluating the combinations based on viability ranks, including a viability rank that assesses whether or not a given combination is balanced in other corresponding hierarchical cells that contains instances of any cells of the given combination.

18. The non-transitory machine-readable medium of claim 16, wherein the instructions cause the computing system to process the given component to determine the additional corresponding hierarchical cells further by:
detecting that two of the combinations include a same cell; and
discarding one or both of the combinations.

19. The non-transitory machine-readable medium of claim 15, wherein the instructions further cause the computing system to discard trivial components prior to or during processing of the components,
wherein a trivial component contains no nontrivial classes or contains a single nontrivial class, and
wherein a nontrivial class is an identical-cell class which includes multiple cells.

20. The non-transitory machine-readable medium of claim 15, wherein the instructions cause the computing system to topologically sort the component-containment graph by:
identifying a cycle in the component-containment graph; and
breaking the cycle in the component-containment graph by removing an edge induced by a corresponding relationship between cells in the source layout design and the circuit layout design, removing an edge induced by an identicality relationship between cells in the source layout design and the circuit layout design, or a combination of both.
